(19) United States
(12) Patent Application Publication
(10) Pub. No.: US 2025/0067811 A1
(43) Pub. Date: Feb. 27, 2025

(54) BATTERY EVALUATION SYSTEM

(71) Applicant: TOYOTA JIDOSHA KABUSHIKI KAISHA, Toyota-shi (JP)

(72) Inventors: Hirofumi HAZAMA, Nagakute-shi (JP); Kouichi YOKOYAMA, Toyota-shi (JP); Kumiko NODA, Nagoya-shi (JP); Mina NISHIGAKI, Toyota-shi (JP)

(73) Assignee: TOYOTA JIDOSHA KABUSHIKI KAISHA, Toyota-shi (JP)

(21) Appl. No.: 18/778,556

(22) Filed: Jul. 19, 2024

(30) Foreign Application Priority Data
Aug. 22, 2023 (JP) 2023-134328

(51) Int. Cl. G01R 31/392; G01R 31/367; G01R 31/382

(52) U.S. Cl. CPC G01R 31/392; G01R 31/367; G01R 31/382

(57) ABSTRACT

A battery evaluation system according to the present disclosure includes: an extraction unit configured to extract pieces of information about a plurality of evaluation items from received information about a secondary battery; an evaluation unit configured to evaluate each of the extracted pieces of information about the plurality of evaluation items and perform a comprehensive evaluation of the secondary battery based on a plurality of results of the evaluation and a plurality of weight coefficients corresponding to the plurality of results of the evaluation; and an output unit configured to output at least a result of the comprehensive evaluation of the secondary battery, in which the evaluation unit evaluates a temperature frequency distribution of the secondary battery based on a degree of deviation between the temperature frequency distribution of the secondary battery and a standard temperature frequency distribution of the secondary battery.

### CROSS REFERENCE TO RELATED APPLICATIONS

This application is based upon and claims the benefit of priority from Japanese patent application No. 2023-134328, filed on Aug. 22, 2023, the disclosure of which is incorporated herein in its entirety by reference.

### BACKGROUND

The present disclosure relates to a battery evaluation system.

In recent years, an accurate evaluation of a secondary battery such as a lithium-ion battery has been required. For example, International Patent Publication No. WO 2020/045033 discloses a presentation apparatus that derives the relative degree of deterioration of secondary battery mounted on the subject vehicle and presents it to the user of the subject vehicle.

### SUMMARY

In International Patent Publication No. WO 2020/045033, the evaluation items for a secondary battery do not include evaluation items such as a temperature frequency distribution from the time point of the start of use of the secondary battery to the time point of the evaluation thereof. Therefore, in International Patent Publication No. WO 2020/045033, two secondary batteries having the same average temperature from the time point of the start of use to the time point of the evaluation may be evaluated as those of equal value despite the difference in the temperature frequency distribution from the start of use to the evaluation point. That is, in International Patent Publication No. WO 2020/045033, there is a problem that a secondary battery cannot be evaluated accurately.

The present invention has been made in view of the aforementioned circumstances, and an object thereof is to provide a battery evaluation system capable of accurately evaluating a secondary battery.

A battery evaluation system according to the present disclosure includes: a reception unit configured to receive information about a secondary battery to be evaluated; an extraction unit configured to extract pieces of information about a plurality of evaluation items from the received information about the secondary battery; an evaluation unit configured to evaluate each of the extracted pieces of information about the plurality of evaluation items and perform a comprehensive evaluation of the secondary battery based on a plurality of results of the evaluation and a plurality of weight coefficients corresponding to the plurality of results of the evaluation; and an output unit configured to output at least a result of the comprehensive evaluation of the secondary battery, in which the plurality of evaluation items include at least an evaluation item regarding a temperature frequency distribution of the secondary battery from a time point of a start of use of the secondary battery to a time point of the evaluation of the secondary battery, and the evaluation unit evaluates the temperature frequency distribution of the secondary battery based on a degree of deviation between the temperature frequency distribution of the secondary battery and a standard temperature frequency distribution of the secondary battery. Since the above battery evaluation system includes, as an evaluation item for a secondary battery, an evaluation item regarding the temperature frequency distribution of the secondary battery, it is possible to evaluate the secondary battery more accurately.

According to the present disclosure, it is possible to provide a battery evaluation system capable of accurately evaluating a secondary battery. The above and other objects, features and advantages of the present disclosure will become more fully understood from the detailed description given hereinbelow and the accompanying drawings which are given by way of illustration only, and thus are not to be considered as limiting the present disclosure.

### BRIEF DESCRIPTION OF DRAWINGS

FIG. 1 is a diagram showing a configuration example of a battery evaluation system according to a first embodiment;

FIG. 2 is a flowchart showing operations of a battery evaluation apparatus provided in the battery evaluation system shown in FIG. 1;

FIG. 3 is a flowchart showing a flow of an evaluation of pieces of information about a plurality of evaluation items for a secondary battery by the battery evaluation apparatus provided in the battery evaluation system shown in FIG. 1;

FIG. 4 is a diagram showing frequency distribution of a remaining capacity of each of a plurality of secondary batteries having the same age; and

FIG. 5 is a diagram showing frequency distribution of a temperature from a time point of the start of use of a secondary battery to be evaluated to a time point of the evaluation thereof.

### DESCRIPTION OF EMBODIMENTS

The present disclosure will be described hereinafter with reference to an embodiment of the present disclosure. However, the following embodiment is not intended to limit the scope of the disclosure according to the claims. Further, all the components/structures described in the embodiment are not necessarily essential as means for solving the problem. For the clarification of the description, the following descriptions and the drawings are partially omitted and simplified as appropriate. The same elements are denoted by the same reference numerals or symbols throughout the drawings, and redundant descriptions are omitted as necessary.

### First Embodiment

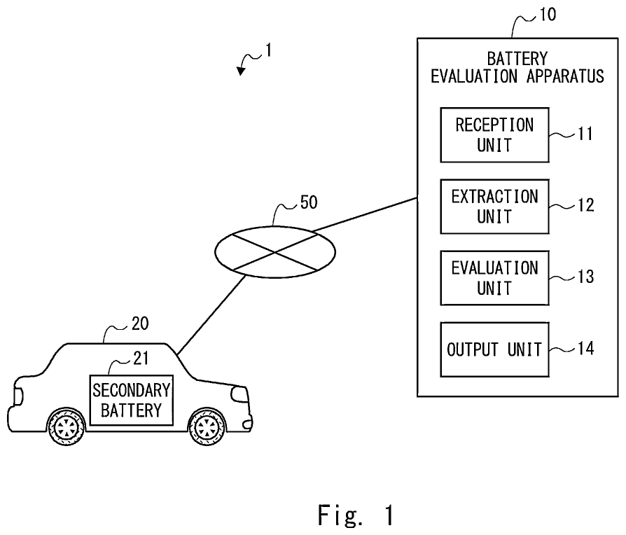

FIG. 1 is a diagram showing a configuration example of a battery evaluation system 1 according to a first embodiment. The battery evaluation system 1 is a system for evaluating the value of a rechargeable secondary battery such as a lithium-ion battery. Note that the battery evaluation system 1 can evaluate a secondary battery more accurately by including an evaluation item regarding the temperature frequency distribution of the secondary battery in the evaluation item of the secondary battery. The details of the above system will be described below.

As shown in FIG. 1, the battery evaluation system 1 includes a battery evaluation apparatus 10, a secondary battery 21 mounted on a vehicle 20, and a network 50. The battery evaluation apparatus 10 itself may also be referred to as a battery evaluation system. The battery evaluation apparatus 10 and the vehicle (or the secondary battery 21) are configured to communicate with each other through the wired or wireless network 50.

Note that, in the present embodiment, a description will be given of an example of a case in which the battery evaluation apparatus 10 evaluates the secondary battery 21 mounted on the vehicle 20. However, the present disclosure is not limited thereto, and the evaluation of the secondary battery 21 mounted on an object other than the vehicle 20 may be performed. For example, the battery evaluation apparatus 10 may evaluate the secondary battery 21 mounted on a mobile terminal such as a smartphone. Further, a description will be given of an example of a case in which the battery evaluation apparatus 10 evaluates the secondary battery 21 via the network 50. However, the present disclosure is not limited thereto, and the battery evaluation apparatus 10 may evaluate the secondary battery 21 directly without using the network 50.

The battery evaluation apparatus 10 is an apparatus that evaluates the value of the secondary battery 21. Specifically, the battery evaluation apparatus includes a reception unit 11, an extraction unit 12, an evaluation unit 13, and an output unit 14.

First, the reception unit 11 receives information about the secondary battery 21 to be evaluated. The information about the secondary battery 21 includes information about the usage status and the usage environment of the secondary battery 21, and includes at least, for example, the age, the remaining capacity, and the average temperature of a time period T1 and the temperature frequency distribution of the time period T1 when the time period from the time point of the start of use of the secondary battery 21 to the time point of the evaluation thereof is set to T1. Here, the age of the secondary battery 21 refers to the time period (i.e., the time period T1) between the time point of the start of use of the secondary battery 21 and the time point of the evaluation thereof. The remaining capacity of the secondary battery 21 refers to the ratio of the full charge capacity of the secondary battery 21 at the time point of the evaluation to the full charge capacity of the secondary battery 21 before the start of use of the secondary battery 21.

In addition, the information about the secondary battery 21 may include the average State Of Charge (SOC) of the time period T1, the SOC frequency distribution of the time period T1, the average amount of charged electricity of the time period T1, the frequency distribution of the amount of charged electricity of the time period T1, the average amount of discharged electricity of the time period T1, the frequency distribution of the amount of discharged electricity of the time period T1, the average value of the voltage difference of each of a plurality of battery cells constituting the secondary battery 21, and the frequency distribution of the voltage difference of each of the plurality of battery cells constituting the secondary battery 21.

The information about the secondary battery 21 is observed by an observation apparatus provided separately from the secondary battery 21 or an observation function when the secondary battery 21 has the observation function, and stored in a storage apparatus (not shown). Then, the reception unit 11 of the battery evaluation apparatus 10 receives the information about the secondary battery 21 stored in the storage apparatus.

The extraction unit 12 extracts pieces of information about a plurality of evaluation items from the information about the secondary battery 21 received by the reception unit 11. In other words, the extraction unit 12 classifies information about the secondary battery 21 received by the reception unit 11 into one of a plurality of evaluation items. The pieces of information about a plurality of evaluation items corresponds to information about the usage status and the usage environment of the secondary battery 21.

The evaluation unit 13 evaluates each of the pieces of information about a plurality of evaluation items extracted by the extraction unit 12. For example, the evaluation unit 13 evaluates the temperature frequency distribution of the secondary battery 21 based on the degree of deviation between the temperature frequency distribution of the secondary battery 21 and the standard temperature frequency distribution of the secondary battery 21 (e.g., the average temperature frequency distribution in the market). Then, the evaluation unit 13 performs a comprehensive evaluation of the secondary battery 21 based on a plurality of evaluation results and a plurality of weight coefficients corresponding to the plurality of evaluation results. Details of an evaluation method by the evaluation unit 13 will be described later.

The output unit 14 outputs the result of the comprehensive evaluation of the secondary battery 21. The result of the comprehensive evaluation output from the output unit 14, for example, is displayed on a monitor of a user terminal of a user who owns the secondary battery 21 or is sent to the user terminal. Alternatively, the result of the comprehensive evaluation output from the output unit 14 may be displayed on a monitor provided in the battery evaluation apparatus 10.

The output unit 14 may further output the evaluation result of each evaluation item of the secondary battery 21. Thus, for example, a user can specify the secondary battery 21 in which the comprehensive evaluation is high while the evaluation of a predetermined item is low.

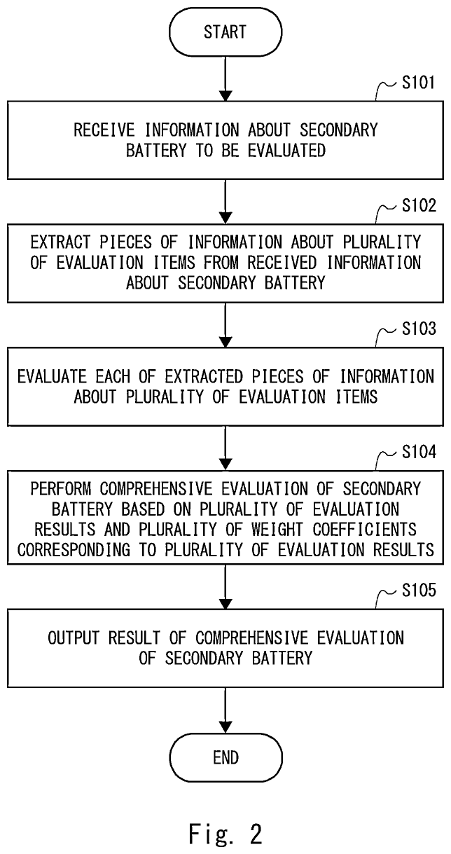

Next, operations of the battery evaluation apparatus 10 will be described with reference to FIG. 2. FIG. 2 is a flowchart showing the operations of the battery evaluation apparatus 10.

First, the battery evaluation apparatus 10 receives information about the secondary battery 21 to be evaluated (Step S101). Then, the battery evaluation apparatus 10 extracts pieces of information about a plurality of evaluation items from the received information about the secondary battery 21 (Step S102). In other words, the battery evaluation apparatus 10 classifies the received information about the secondary battery 21 into one of a plurality of evaluation items. Then, the battery evaluation apparatus 10 evaluates each of the extracted pieces of information about the plurality of evaluation items (Step S103). For example, the evaluation unit 13 evaluates the temperature frequency distribution of the secondary battery 21 based on the degree of deviation between the temperature frequency distribution of the secondary battery 21 and the standard temperature frequency distribution of the secondary battery 21 (e.g., the average temperature frequency distribution in the market). Then, the battery evaluation apparatus 10 performs a comprehensive evaluation of the secondary battery 21 based on a plurality of evaluation results and a plurality of weight coefficients corresponding to the plurality of evaluation results (Step S104). Then, the battery evaluation apparatus 10 outputs the result of the comprehensive evaluation of the secondary battery 21 (Step S105).

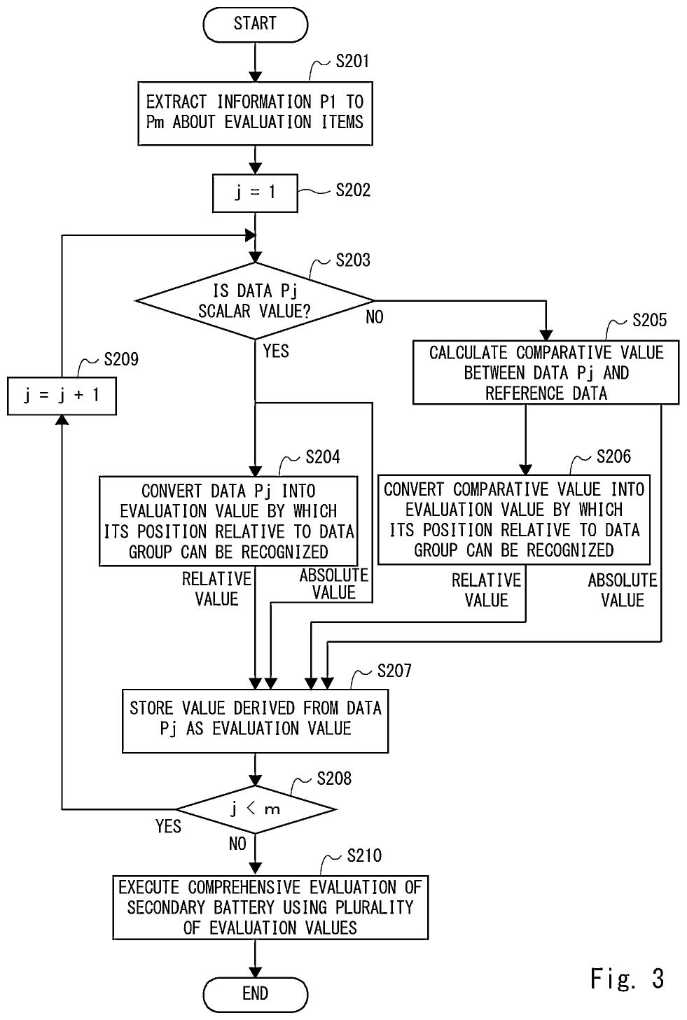

FIG. 3 is a flowchart showing a flow of an evaluation of pieces of information about a plurality of evaluation items for the secondary battery 21 by the battery evaluation apparatus 10. The flowchart shown in FIG. 3 corresponds to the processes of Steps S102 to S104 in FIG. 2.

As shown in FIG. 3, the battery evaluation apparatus 10 extracts information P1 to information Pm about m (m is an integer of two or more) evaluation items from the received information about the secondary battery 21 (Step S201). In the following description, the information P1 to the information Pm about evaluation items are also referred to as data P1 to data Pm. Then, a value 1 is assigned to a variable j (Step S202). Then, the battery evaluation apparatus 10 determines whether or not the data Pj (i.e., the data P1) is a scalar value (Step S203).

For example, when the data Pj is a scalar value (YES in Step S203), the battery evaluation apparatus 10 converts the data Pj into an evaluation value (e.g., a deviation value in the market) by which its position relative to the data group can be recognized (Step S204). Then, the battery evaluation apparatus 10 stores each of the converted value (the relative value) of the data Pj and the absolute value of the data Pj as an evaluation value of the data Pj (Step S207).

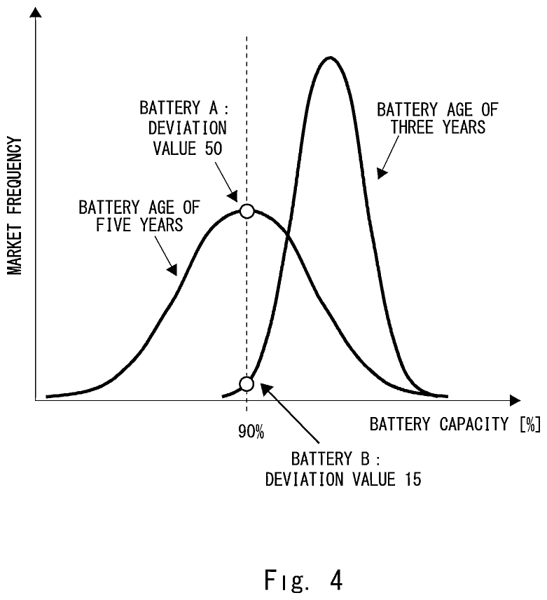

Here, the data Pj represented by a scalar value refers to data that can be represented by a single numerical value, such as the age or the residual capacity. For example, when the data Pj is data representing remaining the remaining capacity “90%”, the battery evaluation apparatus 10 stores each of the absolute value “90%” of the remaining capacity and the deviation value (the relative value) of the remaining capacity of the data Pj relative to the remaining capacities of a plurality of other secondary batteries having the same age as an evaluation value of the data Pj. In the example shown in FIG. 4, a secondary battery A, whose age is five years and remaining capacity shows 90%, shows a medium deviation value of 50 since the remaining capacity is average compared to a plurality of other secondary batteries whose age is five years, while a secondary battery B, whose age is three years and remaining capacity shows 90%, shows a low deviation value of 15 since the remaining capacity is small compared to a plurality of other secondary batteries whose age is three years.

On the other hand, when the data Pj is not a scalar value (NO in Step S203), the battery evaluation apparatus 10 compares the data Pj with reference data (e.g., the market average) and calculates a numerical value representing a comparison result (Step S205).

Here, the data Pj that is not a scalar value refers to data that cannot be represented by a single numerical value, such as the temperature frequency distribution (in other words, data represented by a plurality of numbers). For example, when the data Pj represents the temperature frequency distribution in the time period T1, the battery evaluation apparatus 10 calculates a comparative value of the temperature frequency distribution of the secondary battery 21 in accordance with the degree of deviation between the temperature frequency distribution of the secondary battery 21 and the standard temperature frequency distribution (the average temperature frequency distribution in the market). Then, the battery evaluation apparatus 10 stores each of the value obtained by converting the calculated comparative value into a value (a deviation value) by which its position relative to the data group can be recognized (Step S206) and the absolute value of the calculated comparative value (for example, the average value (the average temperature) in the time period T1) as an evaluation value of the data Pj (Step S207).

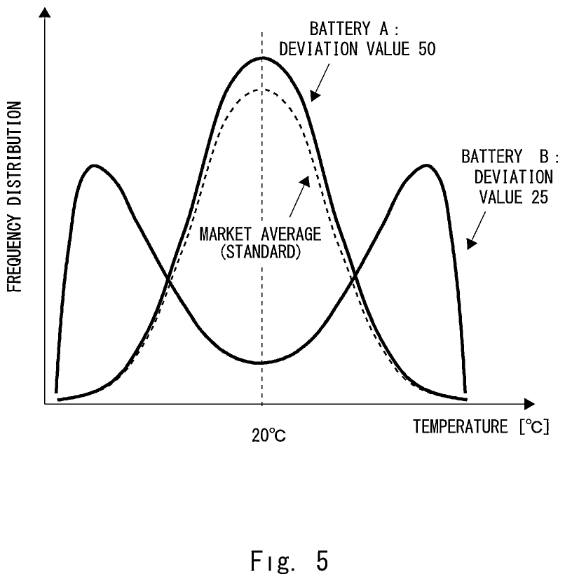

In the example shown in FIG. 5, the secondary battery A shows a medium deviation value of 50 since the degree of deviation between the temperature frequency distribution (the solid line) of the secondary battery A and the standard temperature frequency distribution (the dashed line) is small, while the secondary battery B shows a low deviation value of 25 since the degree of deviation between the temperature frequency distribution (the solid line) of the secondary battery B and the standard temperature frequency distribution (the dashed line) is large. Further, both the average temperature of the time period T1 of the secondary battery A and the average temperature of the time period T1 of the secondary battery B indicate 20 degrees.

Note that when the data Pj is represented by a plurality of numerical values, a correlation (a degree of deviation) r between the data Pj and the reference data is calculated, for example, by the following expression (1), where n represents the number of numerical values constituting the data Pj, xi represents the i-th numerical value out of the n numerical values constituting the data Pj, and yi represents the i-th numerical value out of the n numerical values constituting the reference data.

Further. x̅ represents the average value of x1 to xn, and y represents the average value of y1 to yn.

$$r = \frac{\frac{1}{n} {\sum }_{i = 1}^{n} ( xi - \overline{x} ) ( yi - \overline{y} )}{\sqrt{\frac{1}{n} {\sum }_{i = 1}^{n} {( xi - \overline{x} )}^{2}} + \sqrt{\frac{1}{n} {\sum }_{i = 1}^{n} {( yi - \overline{y} )}^{2}}} \qquad ( 1 )$$

After that, when j<m (YES in Step S208), the value of j is increased by one (Step S209), and then the processes in Steps S203 to 207 are repeated. That is, the processes for data P2 are performed. Then, when j<m no longer holds (NO in Step S208), that is, when j=m, the battery evaluation apparatus 10 executes the comprehensive evaluation of the secondary battery 21 using a plurality of stored evaluation values (Step S210).

The comprehensive evaluation value is calculated, for example, by the following expression (2), where wi represents a weight coefficient for an evaluation value i, Xi represents the value of the evaluation value i, and f (Xi) represents a function of Xi.

$$The comprehensive evaluation value = \sum wi \times f ( Xi ) + constant \qquad ( 2 )$$

For example, in the secondary battery A, X1=the remaining capacity of 90%, X2=the deviation value of 50 in the remaining capacity, X3=the average elapsed temperature of 20° C., X4=the deviation value of 50 in the temperature frequency distribution, and therefore the comprehensive evaluation value of the secondary battery A is expressed as follows.

The comprehensive evaluation value of the secondary battery A=1×X1−0.1×(50−X2)−0.05×(20−X3)\hat{ }2−0.05×(65−X4)=1×90−0.1×(50−50)−0.05×(20−20)\hat{ }2−0.05×(65−50)=89.25

Further, for example, in the secondary battery B, X1=the remaining capacity of 90%, X2=the deviation value of 15 in the remaining capacity, X3=the average elapsed temperature of 20° C., X4=the deviation value of 25 in the temperature frequency distribution, and therefore the comprehensive evaluation value of the secondary battery B is expressed as follows.

The comprehensive evaluation value of the secondary battery B=1×X1−0.1×(50−X2)−0.05×(20−X3)\hat{ }2−0.05×(65−X4)=1×90−0.1×(50−15)−0.05×(20−20)\hat{ }2−0.05×(65−25)=84.5

In other words, the battery evaluation apparatus 10 evaluates the secondary battery A higher than the secondary battery B.

As described above, the battery evaluation system according to the present embodiment can evaluate a secondary battery more accurately by including an evaluation item regarding the temperature frequency distribution of the secondary battery in the evaluation item of the secondary battery.

Further, in the present disclosure, it is possible to implement some or all of the processes performed in the battery evaluation apparatus 10 by causing a Central Processing Unit (CPU) to execute a computer program.

The above-described program includes instructions (or software codes) that, when loaded into a computer, cause the computer to perform one or more of the functions described in the embodiments. The program may be stored in a non-transitory computer readable medium or a tangible storage medium. By way of example, and not a limitation, non-transitory computer readable media or tangible storage media can include: a Random-Access Memory (RAM), a Read-Only Memory (ROM), a flash memory, a Solid-State Drive (SSD), or other types of memory technologies; a CD-ROM, a Digital Versatile Disc (DVD), a Blu-ray (Registered Trademark) disc, or other types of optical disc storages; and a magnetic cassette, a magnetic tape, a magnetic disc storage, or other types of magnetic storage devices. The program may be transmitted on a transitory computer readable medium or a communication medium. By way of example, and not a limitation, transitory computer readable media or communication media can include electrical, optical, acoustical, or other forms of propagated signals.

The whole or part of the embodiments disclosed above can be described as, but not limited to, the following supplementary notes.

### Supplementary Note 1

A battery evaluation method performed by a battery evaluation system, the battery evaluation method comprising:
receiving information about a secondary battery to be evaluated;
extracting pieces of information about a plurality of evaluation items from the received information about the secondary battery;
evaluating each of the extracted pieces of information about the plurality of evaluation items and performing a comprehensive evaluation of the secondary battery based on a plurality of results of the evaluation and a plurality of weight coefficients corresponding to the plurality of results of the evaluation; and
outputting at least a result of the comprehensive evaluation of the secondary battery, wherein
the plurality of evaluation items include at least an evaluation item regarding a temperature frequency distribution of the secondary battery from a time point of a start of use of the secondary battery to a time point of the evaluation of the secondary battery, and
in the comprehensive evaluation of the secondary battery, the temperature frequency distribution of the secondary battery is evaluated based on a degree of deviation between the temperature frequency distribution of the secondary battery and a standard temperature frequency distribution of the secondary battery.

### Supplementary Note 2

A control program for causing a computer to:
receive information about a secondary battery to be evaluated;
extract pieces of information about a plurality of evaluation items from the received information about the secondary battery;
evaluate each of the extracted pieces of information about the plurality of evaluation items and perform a comprehensive evaluation of the secondary battery based on a plurality of results of the evaluation and a plurality of weight coefficients corresponding to the plurality of results of the evaluation; and
output at least a result of the comprehensive evaluation of the secondary battery, wherein
the plurality of evaluation items include at least an evaluation item regarding a temperature frequency distribution of the secondary battery from a time point of a start of use of the secondary battery to a time point of the evaluation of the secondary battery, and
in the comprehensive evaluation of the secondary battery, the temperature frequency distribution of the secondary battery is evaluated based on a degree of deviation between the temperature frequency distribution of the secondary battery and a standard temperature frequency distribution of the secondary battery.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A battery evaluation system comprising:
a reception unit configured to receive information about a secondary battery to be evaluated;
an extraction unit configured to extract pieces of information about a plurality of evaluation items from the received information about the secondary battery;
an evaluation unit configured to evaluate each of the extracted pieces of information about the plurality of evaluation items and perform a comprehensive evaluation of the secondary battery based on a plurality of results of the evaluation and a plurality of weight coefficients corresponding to the plurality of results of the evaluation; and
an output unit configured to output at least a result of the comprehensive evaluation of the secondary battery, wherein
the plurality of evaluation items include at least an evaluation item regarding a temperature frequency distribution of the secondary battery from a time point of a start of use of the secondary battery to a time point of the evaluation of the secondary battery, and
the evaluation unit evaluates the temperature frequency distribution of the secondary battery based on a degree of deviation between the temperature frequency distribution of the secondary battery and a standard temperature frequency distribution of the secondary battery.

2. The battery evaluation system according to claim 1, wherein the plurality of evaluation items include at least an evaluation item regarding a capacity of the secondary battery.

3. The battery evaluation system according to claim 1, wherein the plurality of evaluation items include at least an evaluation item regarding an elapsed time from the time point of the start of use of the secondary battery to the time point of the evaluation of the secondary battery.

4. The battery evaluation system according to claim 1, wherein the plurality of evaluation items include at least an evaluation item regarding an average temperature of the secondary battery from the time point of the start of use of the secondary battery to the time point of the evaluation of the secondary battery.

5. The battery evaluation system according to claim 1, wherein the evaluation unit multiplies each of the plurality of results of the evaluation by the plurality of weight coefficients corresponding to the plurality of results of the evaluation and then adds results of the multiplication to each other, thereby calculating the comprehensive evaluation of the secondary battery.
